(19) United States
(12) Patent Application Publication
(10) Pub. No.: US 2008/0157385 A1
(43) Pub. Date: Jul. 3, 2008

(54) IC package with integral vertical passive delay cells

(76) Inventors: Heping Yue, Plano, TX (US); Hongwei Liang, Richardson, TX (US); Michael A. Lamson, Anna, TX (US)

Correspondence Address: TEXAS INSTRUMENTS INCORPORATED, P O BOX 655474, M/S 3999, DALLAS, TX, 75265, US

(21) Appl. No.: 11/618,117

(22) Filed: Dec. 29, 2006

(51) Int. Cl. H01L 23/538; G06F 17/50; H01L 21/768

(52) U.S. Cl. 257/773; 438/667; 438/618; 716/10; 716/6; 257/E21.575; 257/E23.174; 257/E23.175

(57) ABSTRACT

Multi-layer semiconductor devices and methods for their assembly are described in which the IC packages are endowed with vertical passive delay cells in order to approximately equalize, within selected design tolerances, the signal propagation delays among electrical traces within the package.

### TECHNICAL FIELD

The invention relates to electronic semiconductor devices and manufacturing. More particularly, the invention relates to packaged microelectronic semiconductor devices and methods adapted to manage signal propagation delays among electric signal traces therein.

### BACKGROUND OF THE INVENTION

Typical semiconductor packages (either flip-chip BGA or wire-bond BGA types) use a radial routing pattern to layout 10 signal paths on the metal layer(s). This inherently creates 10 signal traces with different lengths. As shown in FIG. 1 (PRIOR ART), on the routing layer(s) 10 of a device, the path lengths of traces 12 in the corner regions 14 are generally longer than the path lengths of traces 12 in the central region 16. The different trace lengths result in different signal propagation times through the various traces. These routing length differences between traces result in package skew, or delay time difference. A certain amount of delay time difference may be acceptable for a given circuit design, but delay time differences can be a problem in circuits where precise timing is required. Generally, as the operating speed of circuits becomes faster, the tolerable level of delay time difference becomes smaller.

The delay time of each trace in a particular device may be calculated from its equivalent inductance and capacitance, (t_{d}=\sqrt{L×C}), which are electrical properties of the trace related primarily to its physical dimensions. Table 1 lists the propagation delays of an 8-bit data bus through a common package as represented by the example of FIG. 1 (PRIOR ART). In a conventional package, it is common to have a range of delay times. As shown, the worst delay skew of the bus in this example is as much as 42 ps, caused by the trace length difference between the shortest trace 5 and the longest trace 0 in the routing layer 10. Such relatively large differences among delays can be detrimental to circuit performance.

TABLE 1

| | | | | Prop. | Delay |
|---|---|---|---|---|---|
| Net Name | Lenth (mm) | L (nH) | C (pF) | delay (ps) | skew (ps) |
| DDR_data[0] | 11.97 | 4.39 | 3.46 | 123 | 0 |
| DDR_data[1] | 10.37 | 3.38 | 2.97 | 100 | 23 |
| DDR_data[2] | 9.57 | 3.11 | 2.81 | 93 | 30 |
| DDR_data[3] | 11.94 | 3.80 | 3.40 | 114 | 10 |
| DDR_data[4] | 8.63 | 2.69 | 2.60 | 84 | 40 |
| DDR_data[5] | 7.29 | 2.68 | 2.46 | 81 | 42 |
| DDR_data[6] | 8.77 | 3.15 | 2.93 | 96 | 27 |
| DDR_data[7] | 10.50 | 3.80 | 3.19 | 110 | 13 |

For example, because package skew contributes to unwanted digital signal timing jitter, it is detrimental to digital or ASIC systems such as DDR (Double Data Rate) data bus interfaces, which require almost identical delays for each signal in the bus. For a digital system with a tight timing budget, or “jitter budget”, it is desirable to implement a package with a minimum jitter for its data and address bus signals. In the context of a PC Board, which is planar, it is known in the arts to use a serpentine routing technique to match trace length between pins at different locations. However, this technique cannot be readily implemented in the context of a package without increasing the package footprint because packages tend to require a much higher density of IO pins and have extremely limited planar area available to use for routing purposes.

Due to the foregoing problems associated with package skew, it is desirable to make all signal routes within a device have substantially similar delays. Due to area constraints, it is extremely difficult, if not impossible, to make all signal routes with an approximately equal trace length using the current state-of-the-art radial routing techniques, either by increasing the routing length of short trace(s) or by decreasing the routing length of long trace(s) in the routing layer. There is simply not enough planar area. Thus, there is a need in the art for methods and devices for providing matched signal trace propagation delays through a semiconductor device package without increasing lateral area.

### SUMMARY OF THE INVENTION

In carrying out the principles of the present invention, in accordance with preferred embodiments thereof, multi-layer semiconductor devices are endowed with vertical passive delay cells in order to approximately equalize, within selected design tolerances, the signal propagation delays among electrical traces within the device.

According to one aspect of the invention, a preferred method is disclosed for approximately matching the signal propagation times of a plurality of traces in a multi-layer semiconductor device having interconnecting metallic traces of various lengths and various signal propagation times. The method includes steps of selecting a first trace having an inherent signal propagation time, and selecting a second trace having a lesser inherent signal propagation time. One or more vertical passive delay cells is provided in the second trace, introducing a predetermined duration of signal propagation delay in order to adjust the signal propagation time of the second trace to approximate the inherent signal propagation time of the first trace.

According to another aspect of the invention, methods include selecting one or more additional traces having an inherent signal propagation time less than inherent signal propagation time of the first trace and providing one or more vertical passive delay cells in the one or more additional traces. In this way, signal propagation delays are introduced in order to adjust the signal propagation times of the one or more additional traces to approximate the inherent signal propagation time of the first trace, and the adjusted signal propagation time of the second trace.

According to another aspect of the invention, the step of providing one or more vertical passive delay cells further includes configuring the geometry of the one or more vertical passive delay cells to tailor the amount of signal propagation delay produced by the delay cells.

According to still another aspect of the invention, in a preferred embodiment, a multi-layer packaged microelectronic semiconductor device has a number of electrical traces coupling terminals located at various horizontal distances from one another. One or more vertical passive delay cells are constructed in one or more of the traces in order to approximately match the signal propagation delay of such trace to that of at least one other trace.

According to another aspect of the invention, packaged microelectronic semiconductor devices according to preferred embodiments of the invention have vertical passive delay cells constructed from metal-filled vias extending from one of the metal layers to another of the metal layers.

The invention has numerous advantages including but not limited to providing methods and devices offering one or more of the following; substantially equalized time delays, reduced jitter, area reduction, and improved performance. These and other features, advantages, and benefits of the present invention can be understood by one of ordinary skill in the arts upon careful consideration of the detailed description of representative embodiments of the invention in connection with the accompanying drawings.

### BRIEF DESCRIPTION OF THE DRAWINGS

The present invention will be more clearly understood from consideration of the following detailed description and drawings in which:

FIG. 1 (PRIOR ART) is an example representative of planar radial routing traces known in the arts;

FIG. 2 is a conceptual perspective overview illustrating an example of preferred embodiments of a vertical passive delay cell according to the invention;

FIG. 3 is a cut-away partial side view of vertical passive delay cells in a preferred embodiment of the invention;

FIG. 4 is a further example of a preferred embodiment of the invention in a partial cut-away side view of a portion of a semiconductor package;

FIG. 5 is an example of an alternative preferred embodiment of the invention in a cut-away side partial side view of a portion of multi-layer semiconductor package;

FIG. 6 is a top, perspective, partially transparent, view of a portion of a multi-layer semiconductor package showing an example of the practice of preferred embodiments of the invention; and

FIG. 7 is a top view of the exemplary embodiment of the invention also shown in FIG. 6.

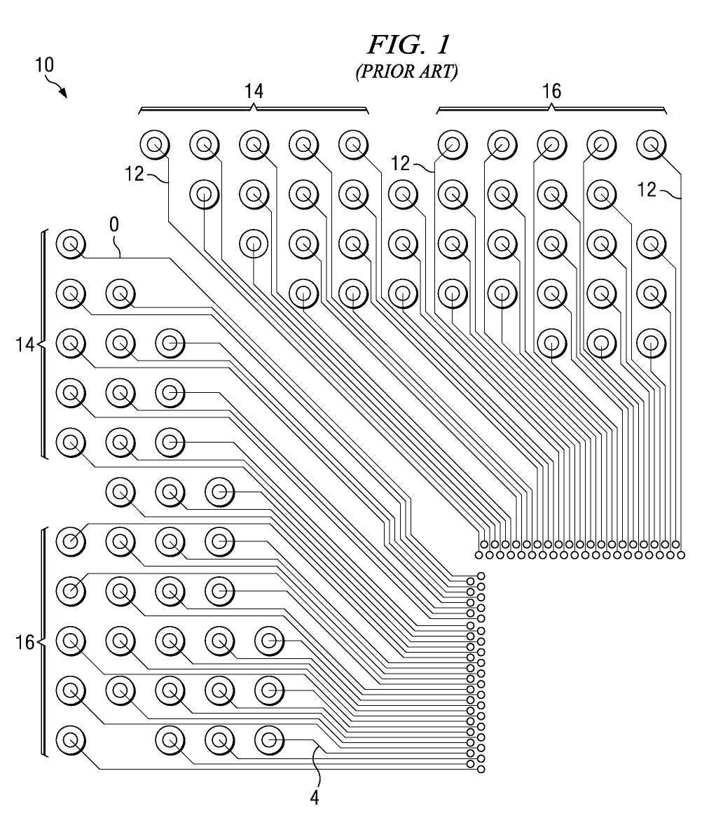

References in the detailed description correspond to like references in the various Figures unless otherwise noted. Descriptive and directional terms used in the written description such as first, second, top, bottom, upper, side, etc., refer to the drawings themselves as laid out on the paper and not to physical limitations of the invention unless specifically noted. The drawings are not to scale, and some features of embodiments shown and discussed are simplified or amplified for illustrating the principles, features, and advantages of the invention.

### DETAILED DESCRIPTION OF PREFERRED EMBODIMENTS

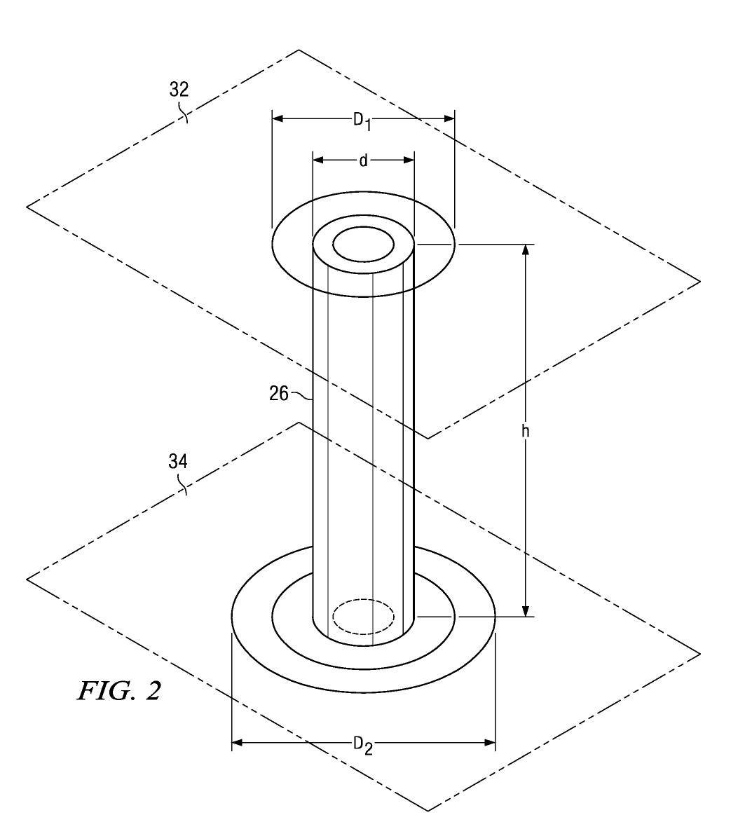

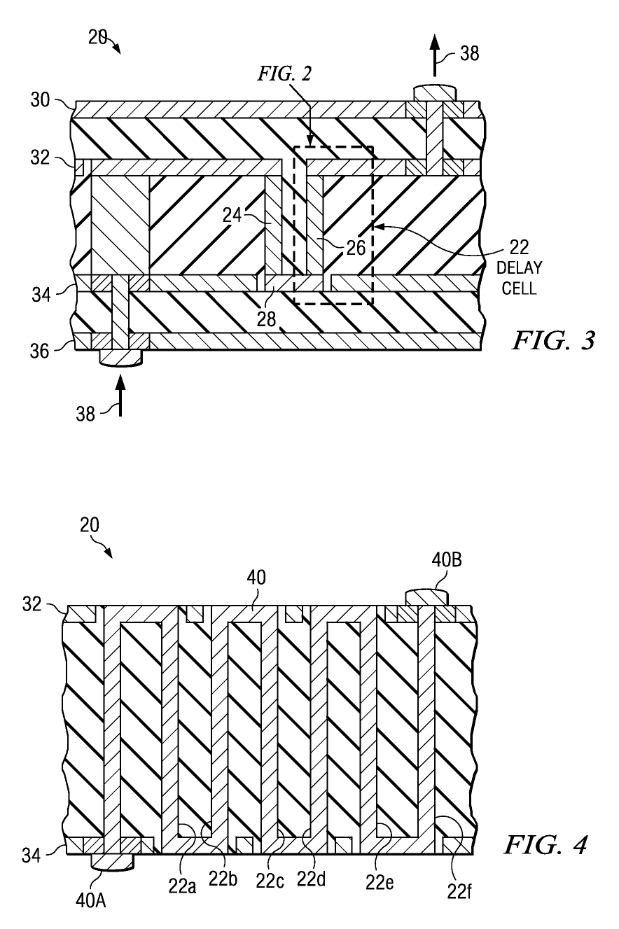

In general, the invention provides devices and methods for improved management of timing delays in multi-layer semiconductor device packages by the integration of one or more vertical passive delay cells within the electrical traces of a multi-layer semiconductor package. The vertical passive delay cells and methods of the invention utilize metallic paths, preferably metal-plated via structures, between the metal layers in a semiconductor package to introduce one or more calibrated increment(s) of propagation delay(s) for those signal traces having shorter inherent propagation delays, usually due to shorter horizontal distances, between pins or terminals. The additional desired amount of delay time is preferably determined by manipulating the equivalent inductance and capacitance of the vertical passive delay cell(s). Referring primarily to FIG. 2, an overview of the principles and practice of preferred exemplary embodiments of the invention are illustrated. As shown in FIG. 2, a conductive delay cell 22(a) preferably has a geometric shape similar to a via formed using techniques known the arts. The delay time (t_{d}) of a delay cell 22(a) is preferably determined by its equivalent capacitance (C) and inductance (L) values, t_{d}=\sqrt{L×C}, which may be calculated based upon the physical characteristics of the delay cell 22(a) using the following formulas:

$$C = \frac{1.41 {ɛ}_{r} {tD}_{1}}{{D}_{2} - {D}_{1}}$$

$$L = 5.08 h [ ln ( \frac{4 h}{d} ) + 1 ]$$

### Where, D₁=diameter of via pad,

D₂=diameter of clearance hole in metal layer,

t=thickness of metal layer,

d=diameter of via,

h=height of via.

Now also referring to FIG. 3, a cut-away partial side view of a package 20 using the invention depicts a close-up view of the structure of two exemplary delay cells 22a and 22b. The delay cells 22a, 22b preferably each include a via, 24 and 26 respectively, filled with metal plating and coupled by a connective segment of metal trace 28. In this example, the multi-layer package 20 includes four metal layers, enumerated sequentially from top to bottom, 30, 32, 34, 36, in the drawing. Thus, in this example of a device and method of the invention, the continuous conductive metal trace path indicated by arrows 38 incorporates two delay cells 22a, 22b, providing a predetermined delay which may be calibrated to match the signal propagation delay of the trace path 38 to that of other trace path(s) (not shown) within the package 20. Since semiconductor packages typically have at least two metal layers, e.g. 32, 34, the invention may be practiced with virtually any type of semiconductor package. Generally, a device having more metal layers has more vertical space and therefore more flexibility to insert vertical passive delay cells to adjust the desired total propagation time according to the invention. The delay obtainable from each delay cell is largely dependent upon its inductance (L) and capacitance (C), which are in turn largely dependent upon the geometry of each delay cell. As may be seen with reference to FIG. 2 and the related formulas herein, the size, and therefore the delay duration (t_{d}) provided by individual delay cells, is largely dependent upon the height (h), and diameter of the via (d), the diameter of the via pad (D1) in the upper delay cell layer 32, the diameter of the clearance hole (D2) in the opposing lower delay cell layer 34, and the thickness (t) of the metal layer(s), 32, 34. Due to their relatively large size, Plated-Through-Hole (PTH) vias traversing the greatest vertical distance (h) between metal layers, e.g., as between layers 32, 34 in this example, are preferably used to construct vertical passive delay cells according to the invention.

Now referring to FIG. 4, a further example of a preferred embodiment of the invention is shown in a cut-away side view of a portion of a semiconductor package 20. A trace 40 electrically connecting point 40A to point 40B includes numerous delay cells 42(a,b, . . . , f). Each delay cell 42(a,b, . . . , f) in this example is preferably configured as shown and described with reference to FIGS. 2 and 3. Thus, the trace 40, in addition to the delay inherent in its horizontal distance from point 40A to point 40B, incorporates an additional cumulative delay occasioned by the sum of the propagation delay of a signal passing through each of the delay cells 42(a,b, . . . , f), i.e.; t_{d42a}+t_{d42b} . . . +t_{d42f}. It should be appreciated by those familiar with the arts that this is accomplished within the same planar footprint of the trace 40 as if a traditional, shorter, primarily horizontal path had been used.

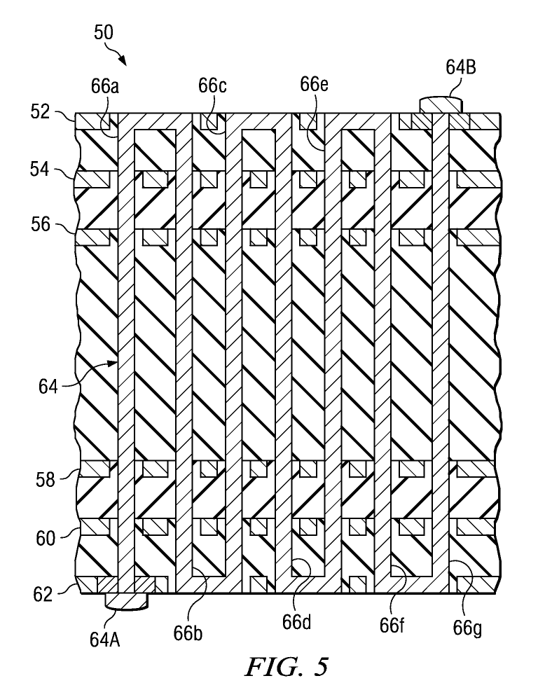

As shown in the cut-away partial side view of FIG. 5, the invention may also be implemented in a device 50 having more numerous metallic layers, in this case six layers, numbered 52, 54, 56, 58, 60, 62, from top to bottom respectively. In this example, a trace path 64 from point 64A to point 64B includes multiple vertical delay cells 66(a,b, . . . , g). As shown in this example, maximum height (h) of the delay cells 66(a,b, . . . , g) may be attained by extending the delay cells 66(a,b, . . . , g) to span from the top layer 52 to the bottom layer 62 of the device 50. Preferably, metal-filled micro-vias are used to construct the delay cells 66(a,b, . . . , g) through the various intervening layers. Although the examples herein show and describe devices having two, four, and six metal layers, those skilled in the arts should recognize that the invention may be practiced in the context of electronic devices having more numerous metal layers. Various alternative embodiments of the invention are possible, such as for example, using combinations of delay cells of non-uniform height, locating delay cells between various layers throughout the device, and adjusting the diameter(s) of portions of the delay cells. Such variations of embodiments may be made in accordance with numerous layout considerations and timing constraints without departure from the principles of the invention. Preferred implementations include ASIC chip packages, for example, which typically have a relatively thick dielectric core layer sandwiched between metal layers. Preferably, vertical passive delay cells may be implemented by adapting package fabrication processes without adding any additional manufacturing process steps.

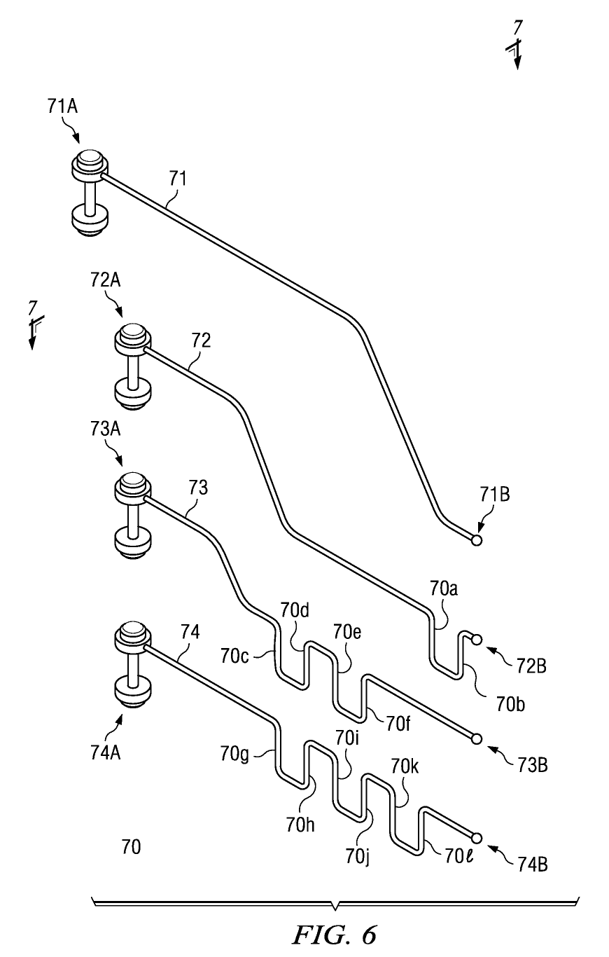

In a top perspective view of an example of the practice of preferred embodiments of the invention, FIG. 6 depicts four traces 71, 72, 73, 74, of various lengths. The values shown in Table 2 represent the time delays inherent in the horizontal path distances in the respective traces.

TABLE 2

| Net name | Length (mm) | L (nH) | C (pF) | Delay (ps) | Skew (ps) |
|---|---|---|---|---|---|
| trace [71] | 11.09 | 4.29 | 3.43 | 121 | 0 |
| trace [72] | 8.43 | 3.18 | 2.81 | 95 | 27 |
| trace [73] | 7.22 | 2.64 | 2.53 | 82 | 40 |
| trace [74] | 5.75 | 2.21 | 2.20 | 70 | 52 |

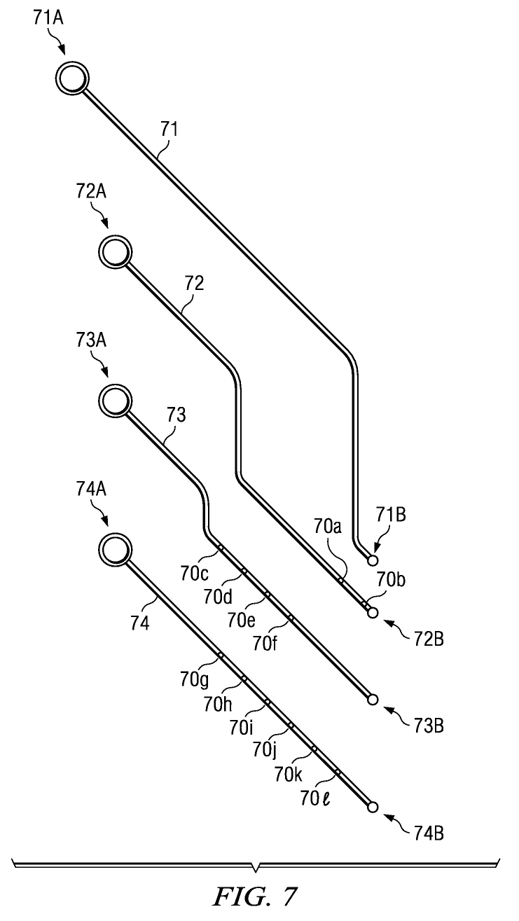

As shown, the differences between the various propagation delays can engender a skew, in this example, as much as 52ps between the longest trace 71 and the shortest trace 74. As shown in FIG. 6, vertical passive delay cells 70(a,b, . . . , l) incorporated into all but the longest trace 71, i.e., traces 72, 73, and 74, may be determined according to the relationships shown and described with reference to FIG. 2 in order to reduce the time delay differences among the traces. As shown in Table 3, the time delay differences are reduced and the skew values are brought to within closer tolerances. It should be noted from the corresponding top view of FIG. 7, that the layout pattern of traces in the routing layer is not affected by the insertion of the delay cells into the shorter traces. That is, the lateral footprint occupied by the traces 71, 72, 73, 74, is not increased by the use of the vertical delay cells 70(a, b, . . . , l) according to the invention.

TABLE 3

| Net name | # of delay cells | L (nH) | C (pF) | delay (ps) | skew (ps) |
|---|---|---|---|---|---|
| trace [71] | 0 | 4.29 | 3.43 | 121 | 0 |
| trace [72] | 2 | 3.99 | 3.48 | 118 | 3 |
| trace [73] | 4 | 3.45 | 3.79 | 114 | 7 |
| trace [74] | 6 | 3.21 | 4.16 | 116 | 6 |

The invention provides advantages including but not limited to circuit timing advantages engendered by incorporating vertical passive delay cells in the paths of shorter electrical traces according to the invention, such as the reduction or elimination (within practical design tolerances) of signal propagation delay skews. Using the invention, the timing budget for a package may potentially be tightened to save precious timing margins for other parts of the circuit or device in high-speed digital systems. While the invention has been described with reference to certain illustrative embodiments, the methods and devices described herein are not intended to be construed in a limiting sense. Various modifications and combinations of the illustrative embodiments as well as other advantages and embodiments of the invention will be apparent to persons skilled in the art upon reference to the description and claims.

We claim:

1. In a multi-layer semiconductor device having a plurality of interconnecting metallic traces of various lengths and various signal propagation times, a method of approximately matching the signal propagation times through a plurality of the traces, the method comprising:
selecting a first trace having an inherent signal propagation time;
selecting a second trace having an inherent signal propagation time less than the inherent signal propagation time of the first trace; and
providing one or more vertical passive delay cells in the second trace, thereby introducing signal propagation delay suitable to adjust the signal propagation time of the second trace to approximate the inherent signal propagation time of the first trace.

2. A method according to claim 1 further comprising the steps of:
selecting one or more additional traces having an inherent signal propagation time less than inherent signal propagation time of the first trace; and
providing one or more vertical passive delay cells in the one or more additional traces, thereby introducing signal propagation delays suitable to adjust the signal propagation times of the one or more additional traces to approximate the inherent signal propagation time of the first trace and the adjusted signal propagation time of the second trace.

3. A method according to claim 1 wherein the step of providing one or more vertical passive delay cells further comprises configuring the geometry of the one or more vertical passive delay cells to tailor the amount of signal propagation delay produced by the delay cells.

4. A method according to claim 1 wherein the step of providing one or more vertical passive delay cells further comprises configuring the geometry of the one or more vertical passive delay cells to adjust the inductance of the vertical passive delay cells to tailor the amount of signal propagation delay produced by the delay cells.

5. A method according to claim 1 wherein the step of providing one or more vertical passive delay cells further comprises configuring the height of the one or more vertical passive delay cells to tailor the amount of signal propagation delay produced by the delay cells.

6. A method according to claim 1 wherein the step of providing one or more vertical passive delay cells further comprises configuring the diameter of the one or more vertical passive delay cells to tailor the amount of signal propagation delay produced by the delay cell.

7. A method according to claim 1 wherein the step of providing one or more vertical passive delay cells further comprises configuring the geometry of the one or more vertical passive delay cells to adjust the capacitance of the vertical passive delay cells to tailor the amount of signal propagation delay produced by the delay cells.

8. A method according to claim 1 wherein the step of providing one or more vertical passive delay cells further comprises configuring the diameter of the via pad of one or more vertical passive delay cells to tailor the amount of signal propagation delay produced by the delay cell.

9. A method according to claim 1 wherein the step of providing one or more vertical passive delay cells further comprises configuring the diameter of the clearance hole in the metal layer of one or more vertical passive delay cells to tailor the amount of signal propagation delay produced by the delay cell.

10. A method according to claim 1 wherein the step of providing one or more vertical passive delay cells further comprises configuring the thickness of the metal layer of one or more vertical passive delay cells to tailor the amount of signal propagation delay produced by the delay cell.

11. A method for manufacturing a packaged IC comprising the steps of:
providing a multi-layer semiconductor device having at least two metal layers;
in at least one of the metal layers, providing a plurality of signal traces for coupling terminals located at various horizontal distances from one another; and
providing one or more vertical passive delay cells in one or more of the traces, thereby approximately matching the propagation delay of at least one trace having one or more vertical passive delay cells to that of at least one other trace.

12. A packaged microelectronic semiconductor device comprising:
an IC having a plurality of metal layers;
in at least one of the metal layers, a plurality of signal traces coupling terminals located at various horizontal distances from one another; and
one or more vertical passive delay cells in one or more of the traces, wherein the signal propagation delay of at least one trace having one or more vertical passive delay cells approximately matches that of at least one other trace.

13. A packaged microelectronic semiconductor device according to claim 12 wherein the one or more vertical passive delay cell further comprises a metal-filled via extending from one of the metal layers to another of the metal layers.

14. A packaged microelectronic semiconductor device according to claim 12 wherein the one or more vertical passive delay cell further comprises a metal-filled pour-through-hole via extending from one of the metal layers to another of the metal layers.

15. A packaged microelectronic semiconductor device according to claim 12 wherein the one or more vertical passive delay cell further comprises a metal-filled micro-via extending from one of the metal layers to another of the metal layers.

16. A packaged microelectronic semiconductor device according to claim 12 wherein the one or more vertical passive delay cell further comprises a metal-filled via extending between the innermost metal layers of the device.

17. A packaged microelectronic semiconductor device according to claim 12 wherein the one or more vertical passive delay cell further comprises a metal-filled via extending between the outermost metal layers of the device.
